(19) United States
(12) Patent Application Publication
(10) Pub. No.: US 2002/0171117 A1
(43) Pub. Date: Nov. 21, 2002

(54) Integrated circuit device

(76) Inventor: Jose Solo De Zaldivar, Waedenswil (CH)

Correspondence Address: Michael E. Marion, c/o PHILIPS ELECTRONICS NORTH AMERICA CORPORATION, Corporate Intellectual Property, 580 White Plains Road, Tarrytown, NY, 10591, US

(21) Appl. No.: 10/028,101

(22) Filed: Dec. 21, 2001

(30) Foreign Application Priority Data
Dec. 22, 2000 (EP) 00204814.8

(51) Int. Cl. H01L 29/00

(52) U.S. Cl. 257/503

(57) ABSTRACT

The invention relates to an integrated circuit device comprising a circuit provided in an active circuit area (4) at a surface of a semiconductor body (1). The circuit comprises circuit devices (2, 3) and an interconnect structure (8) comprising at least one patterned metal layer (5, 6) for interconnecting circuit devices (2, 3) so as to form the circuit. The patterned metal layer (5, 6) is disposed over the circuit devices (2, 3). The circuit further comprises a layer of passivating material (9) disposed atop the interconnect structure (8) and a bump electrode (11, 12, 13) for connection of the circuit to the outside world. The bump electrode (11, 12, 13) lies substantially perpendicularly above the active circuit area (4). According to the invention, the circuit devices (2, 3) are substantially directly electrically connected to the bump electrode (11, 12, 13) by means of an electrical connection (10) extending from the interconnect structure (8) and passing through the layer of passivating material (9).

The invention relates to an integrated circuit device comprising a circuit provided in an active circuit area at a surface of a semiconductor body, said circuit comprising circuit devices, an interconnect structure comprising at least one patterned metal layer for interconnecting circuit devices so as to form the circuit, said patterned metal layer being disposed in an overlying relationship relative to the circuit devices, a layer of passivating material disposed atop the interconnect structure, and a bump electrode for connection of the circuit to the outside world, said bump electrode lying substantially perpendicularly above the active circuit area.

The invention further relates to a method of manufacturing an integrated circuit device, comprising the following steps:

providing a semiconductor body with circuit devices,

providing an interconnect structure comprising at least one patterned metal layer for interconnecting said circuit devices so as to form a circuit, said patterned metal layer being provided in an overlying relationship relative to the circuit devices,

providing a layer of passivating material atop the interconnect structure,

providing a via extending from the interconnect structure and passing through the layer of passivating material, and

growing a bump electrode by means of electroplating, said bump electrode being grown on top of the via contact hole.

The active circuit area is understood to mean the area at a surface of a semiconductor body where circuit devices are provided. These circuit devices may comprise active devices such as, for example, transistors or diodes, as well as passive devices such as, for example, resistors or capacitors.

An integrated circuit device of the type mentioned in the opening paragraph is known from JP-A-9 283 525. The integrated circuit device described therein comprises active circuit devices, such as MOS transistors, provided in an active domain at a surface of a semiconductor body. An interconnect structure is disposed over the active circuit devices, which structure is provided with an interlayer insulating film. A via is formed in said interlayer insulating film for connecting the interconnect structure with an aluminum pad which is an external leading-out electrode. The active domain is formed almost immediately below the aluminum pad. A passivation film provided with a pad opening section is formed on the aluminum pad. Finally, a bump electrode is formed which is connected to the aluminum pad through the pad opening section in the passivation film.

The known integrated circuit device is relatively complicated.

It is an object of the invention to provide an integrated circuit device of the kind mentioned in the opening paragraph which is less complicated and easier to manufacture.

According to the invention, this object is achieved in that the circuit devices are substantially directly electrically connected to the bump electrode by means of an electrical connection extending from the interconnect structure and passing through the layer of passivating material.

By omitting the aluminum pad for connection to the bump, the integrated circuit device becomes less complicated than the integrated circuit device known from the prior art. Because of the reduction of the number of layers, fewer process steps are required and therefore the method of manufacturing the integrated circuit device is simplified.

Further on, the integrated circuit device according to the invention has the advantage of area reduction, because the bump electrode lies substantially perpendicularly above the active circuit area. This miniaturisation is especially important in integrated circuit devices with a large number of bump electrodes, such as those devices applied as display driver ICs. It has been found that functionally the integrated circuit device according to the invention is not different from the integrated circuit device known from the prior art, i.e. the bumping process to attach the device on a carrier does not need to be changed.

It is an advantage of the device according to the invention that the parasitic capacitance is reduced. In the device of the prior art the aluminum pad that has lateral dimensions comparable to the bump electrode, is present below the passivation layer. As a result it is separated from underlying interconnectlines and/or the electrodes of an active element through one into metal dielectrical layer. In the device of the invention, the separation between bump electrode and the underlying interconnectlines includes the passivation, layer with a preferable thickness of 1 micron or larger. Further on, any dielectric material with a low dielectric constant, such as HSQ, MSQ, Silk and porous silica, can be provided directly under the passivation layer.

An embodiment of the integrated circuit device according to the invention is characterized in that the bump electrode comprises a first sublayer and a second sublayer, said first sublayer being an intermediate layer and said second sublayer being a bump.

It has been observed by the inventors that the relatively small contact area of a via does not give the obligation of an additional metal layer. Such an additional metal layer was necessary in the prior art to provide the aluminum pad. The vias through the passivation layer are aligned with the interconnect structure with conventional alignment means, e.g. optical or mechanical, as in a damascene process.

The method of manufacturing an integrated circuit device according to the invention is characterized in that the step of providing a via is immediately followed by the step of growing of a bump electrode.

These and other aspects of the invention will be apparent from and elucidated with reference to the embodiments described hereinafter. In the drawings:

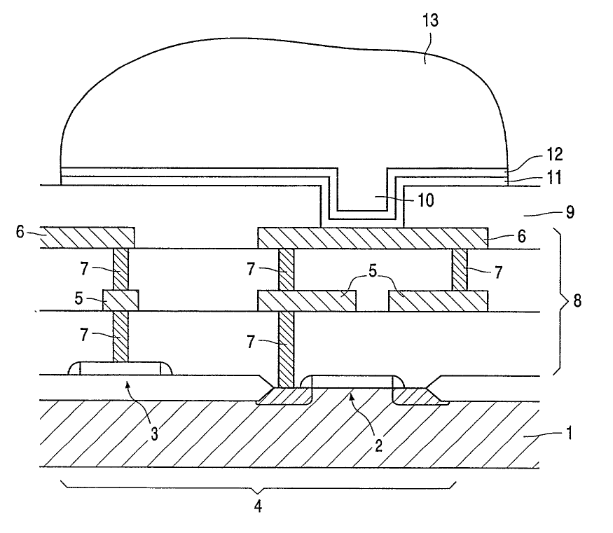

FIG. 1 shows in diagrammatic cross-sectional view a circuit, of which only a part is shown, provided in an active circuit area of an integrated circuit device in accordance with the invention.

For reasons of clarity, the invention is illustrated below on the basis of an integrated circuit device comprising a MOS transistor only. It will be evident, however, to those skilled in the art that the integrated circuit device may contain a plurality of active circuit devices, which need not to be restricted to MOS transistors, but may include bipolar transistors or DMOS/VDMOS transistors as well. Accordingly, the invention is applicable to CMOS and BICMOS integrated circuit devices in general.

The integrated circuit device shown in FIG. 1 comprises a circuit comprising circuit devices, which in this embodiment comprise a MOS transistor (2) and a poly track (3). The circuit is provided in an active circuit area (4) at a surface of a semiconductor body (1). An interconnect structure (8) is provided over the circuit devices (2, 3) for interconnecting the circuit devices (2, 3) so as to form the circuit. In this embodiment, the interconnect structure (8) comprises a first patterned metal layer (5), a second patterned metal layer (6), and interconnection vias (7). A layer of passivating material (9) is disposed on top of the interconnection structure (8). This layer of passivating material (9) may comprise, for example, Si₃N₄ or SiO₂. The circuit, the interconnect structure (8), and the layer of passivating material (9) are all provided in a manner well known to a person skilled in the art. By means of a photostep and etching, a via (10) is formed extending from the second patterned metal layer (6) and passing through the layer of passivating material (9). Immediately after the via (10) has been formed, (i.e. without any intermediate process steps) a barrier layer (11) is provided on the layer of passivating material (9) and in the via contact hole (10), for example, by means of a sputtering process. This barrier layer (11) comprises, for example, TiW or Ti/Pt. The barrier layer (11) is relatively thin compared with the layer of passivating material (9) and has a thickness of about 200 to 300 nm. On top of the barrier layer (11) a metal layer (12) is disposed, for example, by means of a sputtering process. This metal layer (12) may comprise, for example, Au and has a thickness of about 100 to 200 nm. Subsequently a Pb/Sn bump (13) is grown on the barrier layer (11) and the metal layer (12) by means of electroplating preceded by a photolitho step for defining the bump dimensions (or size). The barrier layer (11), the metal layer (12) and the bump (13) together form a bump electrode. The bump electrode forms a direct connection from the circuit to the outside world and lies substantially perpendicularly above the active circuit area (4).

In a further embodiment, a Au bump (13) is used. In this embodiment the metal layer (12) may be omitted and the Au bump (13) may be grown directly on the barrier layer (11) which may comprise, for example, TiW or Ti/Pt. Instead of Pb/Sn or Au, other electrically conducting materials such as Sn, Ag, Cu, Bi, In and Zn as well as alloys thereof can be used for the bump (13). This is not only attractive from a cost perspective, but also from an environmental perspective.

In an even further embodiment, the bump electrode may contain copper or aluminum. This bump electrode can be provided then on a substrate, with a second electrode. Wherein an intermediate layer is present between the bump electrode and the substrate. The bump electrode and the second electrode will form a connection structure, such as described in the non-prepublished application with number EP01000680.7 (PHCH000026), which is herein incorporated by reference.

1. An integrated circuit device comprising a circuit provided in an active circuit area (4) at a surface of a semiconductor body (1), said circuit comprising circuit devices (2, 3), an interconnect structure (8) comprising at least one patterned metal layer (5, 6) for interconnecting circuit devices (2, 3) so as to form the circuit, said patterned metal layer (5, 6) being disposed in an overlying relationship relative to the circuit devices (2, 3), a layer of passivating material (9) disposed atop the interconnect structure (8), and a bump electrode (11, 12, 13) for connection of the circuit to the outside world, said bump electrode (11, 12, 13) lying substantially perpendicularly above the active circuit area (4), the circuit devices (2, 3) are substantially directly electrically connected to the bump electrode (11, 12, 13) by means of an electrical connection (10) extending from the interconnect structure (8) and passing through the layer of passivating material (9).

2. An integrated circuit device as claimed in claim 1, characterized in that the bump electrode (11, 12, 13) comprises a first sublayer and a second sublayer, said first sublayer being an intermediate layer (11, 12) and said second sublayer being a bump (13).

3. An integrated circuit device as claimed in claim 2, characterized in that the intermediate layer comprises a barrier layer (11) and that the bump (13) is a gold bump.

4. An integrated circuit device as claimed in claim 2, characterized in that the intermediate layer comprises a barrier layer (11) and a metal layer (12) and that the bump (13) is a solder bump.

5. A method of manufacturing an integrated circuit device, comprising the following steps:
providing a semiconductor body (1) with circuit devices (2, 3),
providing an interconnect structure (8) comprising at least one patterned metal layer (5, 6) for interconnecting said circuit devices (2, 3) so as to form a circuit, said patterned metal layer (5, 6) being provided in an overlying relationship relative to the circuit devices (2, 3),
providing a layer of passivating material (9) atop the interconnect structure (8),
providing a via (10) extending from the interconnect structure (8) and passing through the layer of passivating material (9), and
growing a bump electrode (11, 12, 13) by means of electroplating, said bump electrode (11, 12, 13) being grown on top of the via (10), characterized in that the step of providing a via (10) is immediately followed by the step of growing of a bump electrode (11, 12, 13).

6. A method of manufacturing an integrated circuit device as claimed in claim 5, characterized in that the step of growing a bump electrode (11, 12, 13) comprises a first substep and a second substep, said first substep comprising providing a TiW barrier layer (11) on the passivation layer (9) and in the via (10), and said second substep comprising growing a gold bump (13) by means of electroplating.

7. A method of manufacturing an integrated circuit device as claimed in claim 5, characterized in that the step of growing a bump electrode (11, 12, 13) comprises a first substep and a second substep, said first substep comprising providing a TiW barrier layer (11) and subsequently a Au metal layer (12) on the passivation layer (9) and in the via (10), and said second substep comprising growing a solder bump (13) by means of electroplating.
